(19) United States
(12) Patent Application Publication
(10) Pub. No.: US 2004/0239415 A1
(43) Pub. Date: Dec. 2, 2004

(54) Methods of predicting power spectral density of a modulated signal and of a multi-h continuous phase modulated signal

(76) Inventor: Christopher Brent Bishop, Apple Valley, CA (US)

Correspondence Address: CHRISTOPHER B. BISHOP, 3690 FARM HILL BLVD., REDWOOD CITY, CA, 94061, US

(21) Appl. No.: 10/854,316

(22) Filed: May 26, 2004

Related U.S. Application Data
(60) Provisional application No. 60/473,603, filed on May 27, 2003.

(51) Int. Cl. H03D 3/00

(52) U.S. Cl. 329/345

(57) ABSTRACT

Methods for predicting the power spectral density of modulated waveforms are based on symmetric and Hermitian forms of a matrix equation. These forms facilitate the use of a Fourier transform method of prediction. In one embodiment, these methods are applied to a particular class of constant-envelope waveforms known commonly as multi-h continuous phase modulation. Various expressions for the power spectral density are then provided as well as an expression for an upper bound. These expressions facilitate the design of waveforms for practical use.

### BACKGROUND

1. Field of the Invention

The present invention is related to methods for predicting power spectral density (PSD) of signals, more particularly to predicting PSD of modulated signals, and most particularly to predicting PSD of multi-h continuous phase modulated signals.

2. Description of Prior Art

The prediction of a power spectral density (PSD) of general modulated signals is an arduous task. The present invention pertains to modulated signals whose PSD's can be predicted, for example, via either periodic or aperiodic Markov processes. Under certain assumptions, the equations for both types of Markov processes are equal.

Within the realm of modulation schemes that can be treated as Markov processes, one can classify some schemes as having a constant amplitude. Within this classification, some schemes have continuous phase, and, finally, a certain set of constant envelope and continuous phase modulated waveforms are identified as multi-h continuous phase modulation.

Multi-h continuous phase modulation (henceforth abbreviated multi-h CPM) is itself a broad class of modulated waveforms. As the name implies, the class includes signals with constant amplitude but varying phase. The phase is generally continuous, but the theory also applies to certain modulations with discontinuous phase such as binary phase shift keying (BPSK). Modulations that are like multi-h CPM but utilize a discontinuous phase modulation are considered herein no differently than multi-h continuous phase modulations.

For a detailed background on multi-h CPM waveforms, consult the book “Digital Phase Modulation” by Anderson, Aulin, and Sundberg, Plenum Press, New York, 1986 as well as the papers cited therein. In that book and in many of the remaining citations, the authors show how to predict the PSD via the autocorrelation function.

Since PSD can vary with time, a usual way to interpret the phrase “PSD” is to mean “time-averaged PSD.”

One method of predicting PSD is to use a straightforward implementation of Markov processes. However, the Markov process method of predicting the PSD yields a very complex matrix equation. The descriptive transition matrix, P, can contain many rows and columns making computation difficult. Furthermore, the equation does not lend itself to physical interpretation.

The autocorrelation method of computing the PSD is often more computationally efficient than the Markov process method, but it suffers from the same lack of physical interpretation. In addition, the autocorrelation method requires an asymptotic expansion for frequencies far from the carrier frequency and usually requires two numerical integrations.

The PSD is one of two important considerations when designing a modulated waveform, the other consideration being how easily the transmitted data symbols can be detected in the presence of noise. This latter consideration is often summarized with a figure of merit, Pₛ, the probability of a symbol error. Ps is often more difficult to compute than the PSD, and like the PSD depends on how the phase transitions from one symbol period to the next.

Historically, the design of modulated waveforms has consisted of

1. Trying different phase paths (such as linear or raised-cosine)

2. Predicting the PSD and the probability of symbol error

3. Comparing results

That is, one guesses at what might constitute a good phase trajectory then computes the PSD and probability of symbol error associated with that phase trajectory to determine how good it is. This ad hoc approach is necessary because the complexity of the underlying equations precludes a more systematic approach.

Because of the complexity of the underlying mathematics of both the PSD and the probability of symbol error, a need exists for exact and approximate equations for predicting the PSD that are less complex than existing equations or that add physical insight to the problem. Certain simplifications, such as bounds on the answers or approximations of answers, are also needed.

Multi-h CPM waveforms are defined by a phase trajectory, Ω(t), and four parameters, J, M, L, and h. These parameters are now defined. Multi-h CPM works by choosing a phase path every to seconds from a set of M possible phase paths. The time period to is called the symbol period. The M possible phase paths are related in that they are scaled multiples of each other. For every positive-going phase path there exists an equal but negative phase path. The scale factors follow the pattern . . . −5, −3, −1, 1, 3, 5, . . . . Thus, if M=2, the scale factors are −1 and 1, and this case is called “binary modulation”; if M=4, the factors are −3, −1, 1, and 3, and this case is called “quaternary modulation”; the scale factors for higher values of M are likewise defined. Because of practical receiver design issues, the value of M is often assumed to be even. The scale factor can be described mathematically as (2m−(M−1)) where m can take on the values 0, 1, 2, . . . M−1.

When a decision is made as to which phase path to follow, a new phase trajectory begins. This new phase trajectory, Ω(t), usually varies continuously from 0 to π radians as time progresses from the starting point until Lt₀ seconds later. From that point on, the phase trajectory is held constant at π radians. The continuous variation in Ω(t) implies a continuous phase modulation. If Ω(t) varies from 0 to π in a discontinuous fashion or if the total phase is anywhere discontinuous, then one can achieve modulations with discontinuous phase, such as BPSK, as described previously.

If L happens to be equal to one, the resulting multi-h CPM scheme is labeled as “full response,” meaning that the entire phase transition from 0 to π takes place during a single symbol period, t₀. If L happens to be greater than one, then the resulting multi-h CPM scheme is labeled as “partial response,” meaning that the entire phase transition from 0 to π takes place during multiple symbol periods.

In addition to the scale factor, the phase trajectory is further multiplied by a value h called the “modulation index.” h is generally positive and is often less than 1, although these restrictions are not necessary. The total phase path for a particular choice of m is therefore h(2m−(M−1)) Ω(t) plus the sum of all previous phase paths.

Furthermore, h can take on multiple values. When h is restricted to a single value, the result is called single-h CPM. Single-h CPM represents a subset of the general class of multi-h CPM waveforms. Multiple values of h are denoted h₀, h₁, . . . h_{J-1}. The phase trajectory is first multiplied by, say, h₀. The next symbol period a new decision is made, and the new phase trajectory is multiplied by h₁. Subsequent symbol periods the phase trajectory is multiplied by h's with higher indices up until h_{J-1}. The next symbol period the cycle repeats and begins again with h₀.

To summarize the parameters, J represents the number of values that h can take, M represents the number of choices in phase paths, L represents the length (in symbol periods) of the generally non-constant portion of the phase trajectory, h scales the magnitude of the phase trajectory, and Ω(t) represents the shape of the phase trajectory. In addition, often h is described as the ratio of two integers. In this case the denominator of h has a value of D.

Also known in the literature is that the number of continuous derivatives of 2(t) directly relates to how fast the PSD decays in frequency In particular, the more continuous derivatives, the faster the PSD decays. This relationship is given by f^{-(2c+4)} where c is the number of continuous derivatives in phase, and f represents frequency expressed in Hertz. Thus, if Ω(t) varies linearly in phase as time progresses from the start of the phase path until L symbol periods later, the derivative of the phase trajectory is discontinuous at the starting and ending points, and the value of c is 0 (that is, there are no continuous derivatives). The ultimate spectral decay rate of this multi-h CPM waveform, regardless of the values of J, M, L, or h, will be as the fourth power of frequency. If c>0, then additional conditions on Ω(t) are required. These conditions are that the first c derivatives of Ω(t) evaluated at the endpoints (t=0 and t=Lt₀) equal zero and that Ω(t) has c continuous derivatives everywhere on its domain.

### SUMMARY

In accordance with aspects of the various described embodiments, a method for predicting the PSD of a modulated waveform is provided. In one aspect, the PSD is predicted by separating previously-known equations for PSD into a symmetric form and proceeding with an evaluation of the result. The symmetric form greatly reduces the computational burden as compared to other techniques.

In another aspect, the symmetric form is reduced to Hermitian form if the transition matrix pre-multiplied by its transpose, P^{T}P, has the property of being idempotent or if some other analytical or numeric technique can help separate the equation.

In another aspect, the Hermitian form reduces to the Fourier transform method.

In other aspects, the symmetric form, the Hermitian form, and the Fourier transform method each can be applied to modulation schemes with various attributes. In particular, the set of transmitted waveforms can have constant amplitudes and varying phases, varying amplitudes and constant phases, both varying amplitudes and varying phases, or other attributes.

In other aspects, the symmetric form, the Hermitian form, and the Fourier transform method each can be applied to the particular case of constant amplitude waveforms known as multi-h CPM.

In other aspects, the actual PSD of multi-h CPM signals can be replaced by an upper bound that allows for easy analysis or facilitates a design methodology for waveforms.

In other aspects, the actual PSD of multi-h CPM signals can be replaced by a Bode plot that allows for easy analysis or facilitates a design methodology for waveforms.

The present method partially fulfills the need for less complex exact and approximate equations for predicting the PSD and improves upon past methods in several ways. The symmetric form, the Hermitian form, and the Fourier transform method all considerably reduce the complexity of the equations as compared to the direct implementation of Markov process methods.

The Fourier transform method allows interpretation of the resulting equation for PSD in terms of equivalent time domain functions. This interpretation adds physical insight to the nature of the PSD.

When one applies the results to particular modulation schemes, the complexity of the equations often can be reduced much further. Furthermore, the Hermitian form and the Fourier transform method result in a number of components that add together to yield the total PSD. By examining these components, one can gain physical insight into why a graph of the PSD has its shape and form. Often, no asymptotic expansion is required for frequencies far from the carrier frequency.

For the case of multi-h CPM and for other cases, use of the Fourier transform method allows the equation for PSD to be reduced to a vector equation rather than a matrix equation required by the Markov process method. A corresponding reduction in complexity and computational effort follows. An upper bound on the actual answer can be found. The bound aids the design of waveforms appropriate for and tailored to particular problems.

### BRIEF DESCRIPTION OF THE DRAWINGS

Non-limiting and non-exhaustive embodiments are described with reference to the following figures, wherein like reference numerals refer to like parts throughout the various views unless otherwise specified.

FIG. 1 is a diagram illustrating a communication system that converts input data to a transmitted signal, propagates the transmitted signal through a channel from which the transmitted signal emerges as a received signal, and then converts the received signal to output data, according to one embodiment.

FIG. 2 is a flow diagram illustrating operational flow for computing PSD at a set of evaluation frequencies, according to one embodiment.

FIG. 3 is a flow diagram illustrating operational flow for computing PSD at a set of evaluation frequencies, according to another embodiment.

### DETAILED DESCRIPTION OF THE INVENTION

Some embodiments of the present invention are directed to methods of computing the PSD of modulated signals including signals that can be described by a Markov process. A particular example of a modulated signal is called multi-h continuous phase modulation, and equations for this case are explicitly developed.

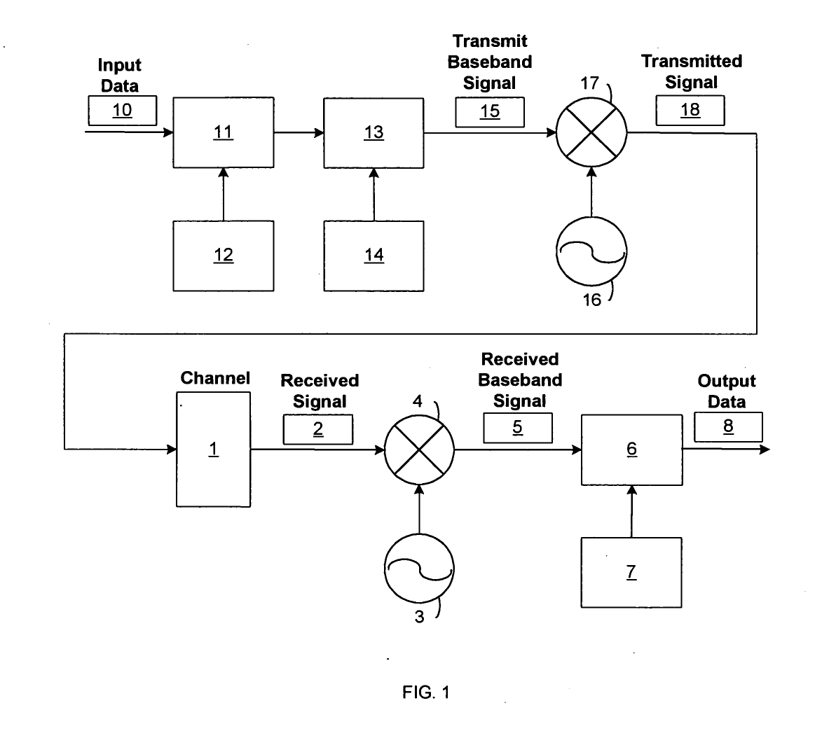

FIG. 1 illustrates one embodiment of a communication system that utilizes modulated signals. In this embodiment the communication system comprises input data 10, a sequence generator 11, a transmitter clock 12, a modulator 13, a waveform generator 14, a transmit baseband signal 15, a carrier frequency generator 16, an upconverter 17, a transmitted signal 18, a channel 1, a received signal 2, a local frequency generator 3, a downconverter 4, a received baseband signal 5, a demodulator 6, a receiver clock 7, and output data 8. Input data 10 are input sequentially to the system. These input data 10 are assumed to have statistical properties that allow them to be treated as deriving from a random process. A sequence generator 11 examines the input data 10 and makes regular decisions about which waveform to transmit next. The regularity of these decisions is maintained by the presence of a transmitter clock 12. The decisions are then passed to a modulator 13 which selects the appropriate waveform from among the alternatives produced by a waveform generator 14 and outputs that waveform as a transmit baseband signal 15. A carrier frequency is produced by a carrier frequency generator 16. An upconverter 17 shifts the transmit baseband signal 15 in frequency to a neighborhood about the carrier frequency, and the result is output as a transmitted signal 18. The transmitted signal 18 propagates through a channel 1. When it emerges from the channel it is then called a received signal 2. A local frequency generator 3, possibly derived from the received signal 2 itself, creates a downcoversion frequency. A downconverter 4 shifts the received signal 2 in frequency to create a received baseband signal 5. A demodulator 6 examines the received baseband signal 5 and makes regular decisions about which data were sent. A receiver clock 7, possibly derived from the received signal 2 itself, maintains the regularity of the decision making process. The results of the decisions made in the demodulator 6 are then presented as output data 8.

The PSD equations as developed herein relate, for example, to the PSD of the transmit baseband signal 15, the transmitted signal 18, the signal in the channel 1, the received signal 2, and the received baseband signal 5.

### General PSD Equations

Using the Markov process approach, the PSD of a modulated signal with constant period is given with minor modification as

$$\begin{matrix}PSD = \frac{1}{{t}_{0}^{2}} {\vert {\sum }_{i = 1}^{{N}_{s}} {p}_{i , i} {h}_{i} \vert}^{2} {\sum }_{n = - ∞}^{∞} δ ( f - \frac{n}{{t}_{0}} ) + \\ \frac{1}{{t}_{0}} {( p h )}^{*} h + \frac{2}{{t}_{0}} Re \{ {( p h )}^{*} P ( {ⅇ}^{- j ω {t}_{0}} ) h \}\end{matrix}$$

In this equation, t₀ is a period length and relates to the timing set by a transmitter clock 12; p, containing elements pᵢⱼ, is a diagonal matrix whose non-zero elements are the stationary probabilities of being in the i^{th} state out of Nₛ possible states; h, containing elements hᵢ, is a vector that contains the Fourier transform of the waveforms produced by a waveform generator 14 during each state; h* is the conjugate transpose of h; f is Hertzian frequency; and ω is radian frequency. \overline{P}(e^{-jωt}^{₀}) is a term that describes how the modulation scheme affects the frequency domain. This term can be written as

$$\overline{P} ( {ⅇ}^{- j ω {t}_{0}} ) = {\sum }_{n = 1}^{∞} {( Pz )}^{k}$$

where P is a matrix containing the probabilities of transition set by the sequence generator 11 and the statistics of the input data 10, and

z−e^{-jωt}^{₀}

\overline{P}(e^{-jωt}^{₀}) can be rewritten as

\overline{P}(e^{-jωt}^{₀})=(I−Pz)⁻¹

where I is an identity matrix. It is possible to show that the diagonal matrix of stationary probabilities, p, has the same non-zero elements as the elements of the eigenvector of P whose associated eigenvalue is one.

The first term of the equation for PSD represents spectral spikes in the PSD. The spectral spikes can be eliminated by judiciously choosing the transition matrix and the elements of h. Because eliminating spectral spikes is usually a design goal, this term is suppressed in the remaining equations. The second term represents the part of the spectrum due to the transmitted signals, themselves, and the third term represents the part of the spectrum that is due in some part to the particular modulation scheme.

Although it is beyond the scope of this application, it can be shown that certain mathematical manipulations can produce a reduced expression for the PSD. The following expression is one embodiment of the symmetric form of the equation for PSD:

$$PSD = \frac{1}{{t}_{0}} {h}^{*} {p ( I - {P}^{T} \overline{z} )}^{- 1} ( I - {P}^{T} P ) {( I - Pz )}^{- 1} h$$

where \overline{z} is the complex conjugate of z.

It is often the case that the term P^{T}P is idempotent. This being the case, one can easily separate the symmetric form into two parts as follows.

$$\begin{matrix}PSD = [ {{h}^{*} ( I - {P}^{T} \overline{z} )}^{- 1} ( I - {P}^{T} P ) \sqrt{\frac{{pp}_{e}^{- 1}}{{N}_{s} {t}_{0}}} ] \\ [ \sqrt{\frac{{p}_{e}^{- 1} p}{{N}_{s} {t}_{0}}} ( I - {P}^{T} P ) {( I - Pz )}^{- 1} h ]\end{matrix}$$

where \sqrt{p} indicates the diagonal matrix whose elements are the square roots of the corresponding elements in p, and pₑ is a diagonal matrix equal to the identity matrix divided by the number of states, Nₛ. That is, p will be equal to pₑ if all states have equal stationary probabilities, and the presence of pₑ⁻¹ cancels the presence of Nₛ. This equation is one embodiment of the Hermitian form of the equations for PSD. If P^{T}P is not idempotent, then Cholesky decomposition or other techniques can be used to accomplish the separation of variables.

One can show that P^{T}P will be idempotent if the transition matrix, P, can be written as the sum of the direct products of certain matrices as follows:

$$P = {\sum }_{i}^{} {E}_{i} ⊗ {r}_{i}$$

The set of matrices, Eᵢ, are orthogonal matrices, and the matrices rᵢ contain zeroes everywhere except that the i^{th} row contains ones. Other conditions on P that lead to a P^{T}P that is idempotent also exist.

Working with the Hermitian form, an expression for a vector of equivalent Fourier transforms is

G(ω)=\sqrt{pₑ⁻¹p}(I−P^{T}P)(I−Pz)⁻¹h

The vector, G(ω), contains the Fourier transforms of a vector of equivalent time domain functions, g(t), on an element-by-element basis. The PSD now can be written as

$$PSD = \frac{1}{{N}_{s} {t}_{0}} {\vert G ( ω ) \vert}^{2}$$

Since G(ω) is a vector, one can alternatively write the PSD as a sum over the individual elements of G(ω):

$$PSD = \frac{1}{{N}_{s} {t}_{0}} {\sum }_{i = 0}^{{N}_{s}} {\vert G ( ω ) \vert}^{2}$$

where the notation suppresses the dependence of G(ω) on i. The last two expressions for PSD represent two embodiments of the Fourier transform method of computing the PSD. One difference between the Hermitian form and the Fourier transform method is that the Hermitian form is a mathematical expression separated into two parts, whereas the Fourier transform method suggests a holistic computational approach to solving the problem. In particular, the Fourier transform method explicitly indicates that only one part of the two parts of the Hermitian form needs to be computed, namely that part labeled G(ω), and that G(ω) can be interpreted as the Fourier transform of some equivalent time domain function.

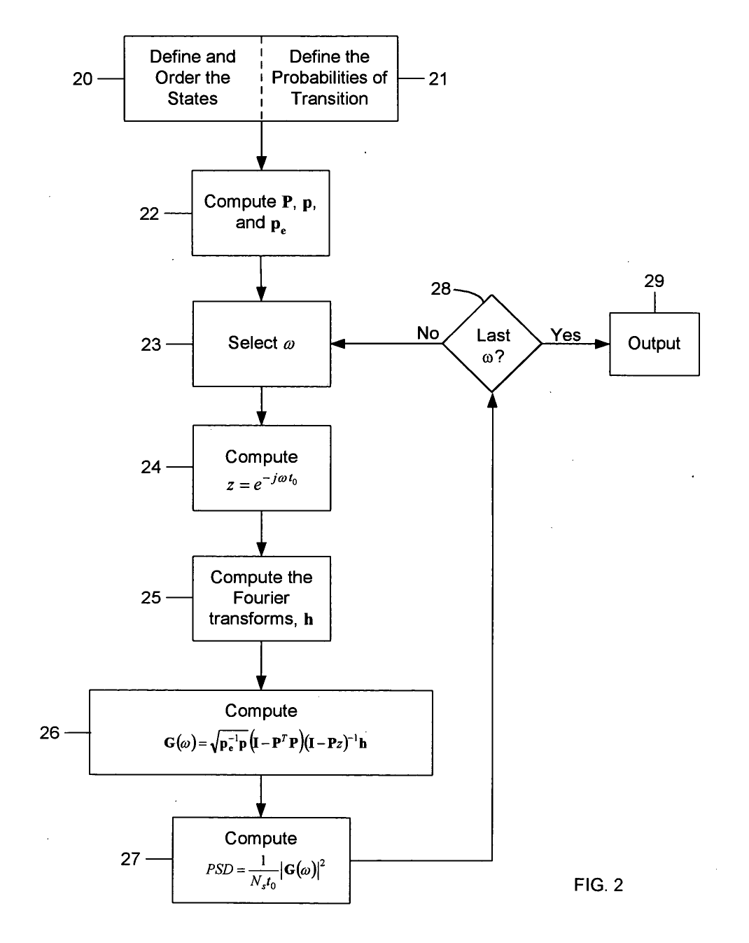

FIG. 2 illustrates one embodiment of an operational procedure for computing PSD. The parts of the operational procedure comprise a state definition block 20, a state transition definition block 21, a matrix computation block 22, a frequency selection block 23, an intermediate variable computation block 24, a Fourier transform computation block 25, an equivalent Fourier transform computation block 26, a PSD computation block 27, a frequency decision block 28, and a data output block 29. Given a modulation scheme whose PSD can be represented in Hermitian form, the first step of this procedure is to define and order the states in the state definition block 20 and define probabilities of transition in the state transition definition block 21. The transition matrix, P, and dependent matrices, p and pₑ, are then computed in the matrix computation block 22. The remaining calculations depend on an evaluation frequency, so a particular evaluation frequency, ω, is selected by the frequency selection block 23. The computation of a variable, z, is performed by the intermediate variable computation block 24. A vector, h, containing the Fourier transforms of the basis functions evaluated at the chosen evaluation frequency is then computed by the Fourier transform computation block 25. A vector containing the equivalent Fourier transforms, G(ω), is found in the equivalent Fourier transform computation block 26; then the PSD evaluated at the evaluation frequency is equal to the squared magnitude of the vector of equivalent Fourier transforms normalized by various constant values. This computation is performed in the PSD computation block 27. The frequency decision block 28 determines whether or not there are more evaluation frequencies. If there are more evaluation frequencies, the procedure returns to the frequency selection block 23; otherwise, the procedure proceeds to the data output block 29 and outputs the results of the computations. At this point the procedure typically ends.

### PSD of Multi-h CPM

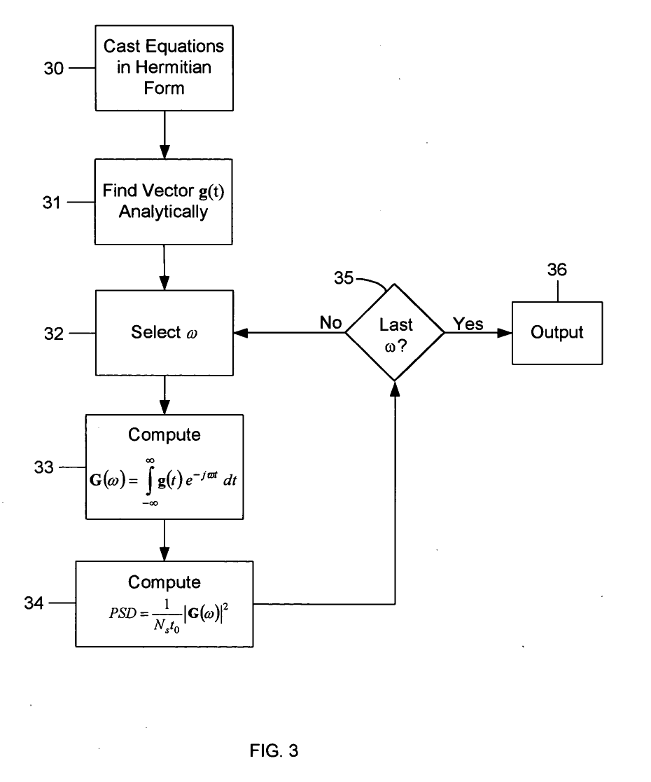

FIG. 3. illustrates another embodiment of an operational procedure for computing PSD. This embodiment represents the preferred embodiment for computing the PSD of multi-h CPM signals and also represents one embodiment of the Fourier transform method. The parts of the operational procedure comprise a Hermitian form block 30, an equivalent time domain function block 31, a selection block 32, a Fourier transform block 33, a PSD block 34, a decision block 35, and an output block 36. In this embodiment, the equations for the PSD are cast in Hermitian form in a Hermitian form block 30, and the vector of equivalent time domain functions g(t) is found analytically in an equivalent time domain function block 31. The remaining calculations depend on an evaluation frequency, so a particular evaluation frequency, ω, is selected in a selection block 32. A vector containing the Fourier transforms of g(t), denoted G(ω), is found in a Fourier transform block 33; then the PSD evaluated at the evaluation frequency is equal to the squared magnitude of the vector of equivalent Fourier transforms normalized by various constant values in a PSD block 34. A decision block 35 determines whether or not there are more evaluation frequencies. If there are more evaluation frequencies, the procedure returns to the selection block 32; otherwise, the procedure proceeds to an output block 36 and outputs the results of the computations. At this point the procedure typically ends.

Multi-h CPM often utilizes equally-likely states, so in the general equations, p=pₑ. The elements of h can be written as the Fourier transforms of a cosine function:

$$\begin{matrix}{h}_{j , m , d} = {\int }_{- ∞}^{∞} cos ( {\sum }_{l = 0}^{L - 1} {h}_{j - l} ( 2 {m}_{l} - ( M - 1 ) Ω ( t + l {t}_{0} ) + π \frac{d}{D} ) ) \\ [ φ ( t ) - φ ( t - {t}_{0} ) ] {ⅇ}^{- j ω t} ⅆ t\end{matrix}$$

The subscripts (j,m,d) on h indicate the state number and index of a particular element. The cosine function is multiplied by Heaviside functions to restrict the domain of the integrand to [0, t₀). Inside the cosine function, the h that denotes the modulation index appears. The subscript on the modulation index should be computed modulo J; the notation suppresses the dependence on the modulo function. For multi-h CPM, the number of states is

Nₛ=2JM^{L}D

This number is computed by considering that j takes on J possible values, m takes on M^{L} possible values, and d takes on 2D possible values.

By properly ordering the states, filling the transition matrix, and performing the mathematics indicated by the General PSD Equations and according to the Fourier transform method, one embodiment of the PSD of a multi-h CPM waveform can be found as

$$\begin{matrix}PSD = \frac{1}{2 {JM}^{L} D {t}_{0}} {\sum }_{i = 0}^{J - 1} {\sum }_{μ}^{} {\sum }_{δ = 0}^{2 D - 1} {\vert {\sum }_{n = 0}^{∞} {\int }_{0}^{{t}_{0}} {g}_{n} ( t ) {ⅇ}^{- j ω ( t + n {t}_{0} )} ⅆ t \vert}^{2} \\ {g}_{n} ( t ) = {F}_{n - 1} cos [ Δ + Σ + σ ] - {F}_{n} cos [ Δ + Σ ] \\ {F}_{k} = {\prod }_{l = 0}^{k} [ \frac{1}{M} {\sum }_{q = 0}^{M - 1} cos ( {h}_{i + n - l} ( 2 q - ( M - 1 ) ) Ω ( t + l {t}_{0} ) ) ] \\ Δ = π \frac{δ}{D} \\ Σ = {\sum }_{l = n + 1}^{n + L - 1} {h}_{i + n - l} ( 2 {μ}_{l - n} - ( M - 1 ) ) Ω ( t + l {t}_{0} )\end{matrix}$$

σ=hᵢ(2μ₀−(M−1))Ω(t+nt₀)

The notation,

$${\sum }_{μ}^{} ,$$

is shorthand notation for the L summations

$${\sum }_{μ} = {\sum }_{{μ}_{0} = 0}^{M - 1} {\sum }_{{μ}_{1} = 0}^{M - 1} ⋯ {\sum }_{{μ}_{L - 1} = 0}^{M - 1}$$

In the above equations and in general, if the upper index of a summation is less than the lower index, the resulting sum is interpreted as being equal to zero. Likewise, if the upper index of a product is less than the lower index of the product, the product is interpreted as being equal to one.

The gₙ(t) represent an equivalent time-domain function defined piece-wise. Thus, g₀(t) represents the equivalent time-domain function during the zeroeth symbol period and is zero elsewhere, g₁(t) represents the function during the first symbol period and is zero elsewhere, and so on. One can define a composite function, g(t), that is zero before the zeroeth symbol period and has the value of gₙ(t) during the n^{th} symbol period. The quantity inside the absolute value function of the PSD then represents the Fourier transform of g(t) and is accordingly denoted G(ω). Note that g(t) and G(ω) depend upon the values indicated by the summations, although this dependence has been suppressed in the notation. Using the notation of G(ω), the equation for PSD can be written alternately as

$$P S D = \frac{1}{2 J {M}^{L} D {t}_{0}} {\sum }_{t = 0}^{J - 1} {\sum }_{μ} {\sum }_{δ = 0}^{2 D - 1} {\vert G ( ω ) \vert}^{2}$$

This form explicitly shows one embodiment of the Fourier transform method as applied to multi-h CPM.

The PSD can therefore be represented as a summation of 2JM^{L}D individual components. These individual components yield insight into the ultimate shape of the PSD. Since all components are non-negative and because they add, the PSD is also non-negative and has a value no less than the value of the largest component at a particular frequency. This helps explain, for instance, why some nulls of PSD curves are filled and why others are deep.

Certain properties of the equation for PSD can also be shown. First, it is easily shown that for n≧L, then g_{n+J}(t) is a scaled multiple of gₙ(t). This property provides a means of replacing the semi-infinite summation over n in the equation for PSD with a finite summation over n.

Second, it can be shown that the total power, P, in the waveform equals one-half regardless of the values of any of the parameters including the phase trajectory. This property is shown by applying Parseval's theorem to the PSD and integrating over all time:

$$\begin{matrix}P = {\int }_{- ∞}^{∞} {\vert P S D ( f ) \vert}^{2} ⅆ f \\ P = \frac{1}{2 J {M}^{L} D {t}_{0}} {\int }_{0}^{∞} {\sum }_{t = 0}^{J - 1} {\sum }_{μ} {\sum }_{δ = 0}^{2 D - 1} {g}^{2} ( t ) ⅆ t = \frac{1}{2}\end{matrix}$$

Third, by applying the general equations for PSD to the case of multi-h CPM and then by utilizing properties of the trigonometric and exponential functions, several other embodiments of the equation for PSD can be achieved. Three particular forms follow.

$$\begin{matrix}PSD = \frac{1}{2 J {M}^{L} {t}_{0}} {\sum }_{t = 0}^{J - 1} {\sum }_{μ} \\ [ {\vert {\sum }_{n = 0}^{∞} {\int }_{0}^{{t}_{0}} ( {F}_{n - 1} cos [ Σ + σ ] - {F}_{n} cos [ Σ ] ) {ⅇ}^{- j ω ( t + n {t}_{0} )} ⅆ t \vert}^{2} + \\ {\vert {\sum }_{n = 0}^{∞} {\int }_{0}^{{t}_{0}} ( {F}_{n - 1} sin [ Σ + σ ] - {F}_{n} sin [ Σ ] ) {ⅇ}^{- j ω ( t + n {t}_{0} )} ⅆ t \vert}^{2} ]\end{matrix}$$

This form is called the “cosine and sine form.” It has the advantage that the dependence on δ has been removed, so the summation over δ has vanished, and the number of states has been reduced. The removal of δ further implies that the modulation index need not be a ratio of two integers.

In the next form, called the “exponential form,” the individual sums involving sines and cosines have been combined into sums over a single complex exponential. Furthermore, the functions Fₖ, Σ, and σ have been expanded.

$$\begin{matrix}PSD = \frac{1}{2 J {M}^{L} {t}_{0}} {\sum }_{t = 0}^{J - 1} {\sum }_{μ} \\ \vert {\sum }_{n = 0}^{∞} \frac{1}{{M}^{n + 1}} {\sum }_{q} {\int }_{0}^{{t}_{0}} ( {ⅇ}^{- j {\sum }_{l = 0}^{n + L - 1} {h}_{t + n - l} {S}_{l - n , l - n + 1} Ω ( t + l {t}_{0} )} - \\ { {ⅇ}^{- j {\sum }_{l = 0}^{n + L - 1} {h}_{t + n - l} {S}_{l - n , l - n} Ω ( t + l {t}_{0} )} ) {ⅇ}^{- j ω ( t + n {t}_{0} )} ⅆ t \vert}^{2}\end{matrix}$$

The notation,

$${\sum }_{q} ,$$

is shorthand notation for the n+1 summations

$${\sum }_{q} = {\sum }_{{q}_{0} = 0}^{M - 1} {\sum }_{{q}_{- 1} = 0}^{M - 1} ⋯ {\sum }_{{q}_{- n} = 0}^{M - 1}$$

This form also requires the definition

$${S}_{i , j} = \{ \begin{matrix}2 {q}_{j} - ( M - 1 ) & j \leq 0 \\ 2 {μ}_{i} - ( M - 1 ) & j > 0\end{matrix}$$

Its benefit is that there is only one absolute value term, a situation that often reduces the required number of computations and facilitates further analysis.

The third form, called the “exponential form with a finite number of summations,” replaces the semi-infinite summation over n with a finite summation over n:

$$\begin{matrix}PSD = \frac{1}{2 J {M}^{L} {t}_{0}} {\sum }_{t = 0}^{J - 1} {\sum }_{μ} & \\ \vert {{\sum }_{n = 0}}^{L - 1} \frac{1}{{M}^{n + 1}} {\sum }_{q} {\int }_{0}^{{t}_{0}} ( {ⅇ}^{- j {Σ}_{1}} - {ⅇ}^{- j {Σ}_{0}} ) {ⅇ}^{- j ω ( t + n {t}_{0} )} ⅆ t + & \\ { \frac{{\sum }_{n = L}^{L + J - 1} \frac{1}{{M}^{n + 1}} {\sum }_{q} {\int }_{0}^{{t}_{0}} ( {ⅇ}^{- j {Σ}_{1}} - {ⅇ}^{- j {Σ}_{0}} ) {ⅇ}^{- j ω ( t + n {t}_{0} )} ⅆ t}{1 - a {ⅇ}^{- j ω J {t}_{0}}} \vert}^{2} & \\ {Σ}_{k} = {\sum }_{l = 0}^{n + L - 1} {h}_{t + n - l} {S}_{l - n , l - n + k} Ω ( t + l {t}_{0} ) & \\ a = {\prod }_{j = 0}^{J - 1} [ \frac{1}{M} {\sum }_{q = 0}^{M - 1} cos ( {h}_{j} ( 2 q - ( M - 1 ) ) π ) ] & \end{matrix}$$

This form has the tremendous benefit of reducing the computation from an infinite number of summations to a finite number of summations and simultaneously avoiding errors caused by truncation of the semi-infinite series.

Three specific PSD computations are of note. First, for the important case of single-h CPM with full response and M=2 (that is, J=1, M=2, L=1), the equations for PSD reduce to

$$PSD = \frac{1}{2 {t}_{0}} {\vert {\int }_{0}^{{t}_{0}} sin ( h Ω ( t ) ) {ⅇ}^{- j ω t} + sin ( h π ) \frac{{ⅇ}^{- j ω {t}_{0}}}{1 - cos ( h π ) {ⅇ}^{- j ω {t}_{0}}} cos ( h Ω ( t ) ) {ⅇ}^{- j ω t} ⅆ t \vert}^{2}$$

Second, in the case that the phase trajectory is linear, meaning

$$Ω ( t ) = \{ \begin{matrix}0 & t < 0 \\ \frac{π}{{Lt}_{0}} t & 0 \leq t < {Lt}_{0} \\ π & {Lt}_{0} \leq t\end{matrix}$$

a closed-form expression for the PSD can always be found regardless of the values of J, M, and L. This result immediately follows from the exponential form of the PSD.

Third, another commonly used phase trajectory is the raised-cosine (RC) trajectory given by

$$Ω ( t ) = \{ \begin{matrix}0 & t < 0 \\ \frac{π}{{Lt}_{0}} t - \frac{1}{2} sin ( \frac{2 π}{{Lt}_{0}} t ) & 0 \leq t < {Lt}_{0} \\ π & {Lt}_{0} \leq t\end{matrix} .$$

From the exponential form of the PSD, it should be apparent to one skilled in the art that the solution relates to Anger functions (sometimes called generalized Bessel functions).

The function, G(ω), and therefore the PSD, can be computed in an alternate manner. G(ω) can be written as

$$G ( ω ) = {\sum }_{n = 0}^{∞} {\int }_{0}^{{t}_{0}} {g}_{n} ( t ) {ⅇ}^{- jω ( t + n {t}_{0} )} ⅆ t$$

Assuming that there are c continuous derivatives in phase, then one can integrate by parts c+1 times to obtain

$$G ( ω ) = \frac{1}{{( jω )}^{c + 1}} {\sum }_{n = 0}^{∞} {\int }_{0}^{{t}_{0}} {g}_{n}^{( c + 1 )} ( t ) {ⅇ}^{- jω ( t + n {t}_{0} )} ⅆ t$$

where gₙ^{(c+1)}(t) is the (c+1)^{th} derivative of gₙ(t). The other terms that result from the integration vanish because of the boundary conditions on Ω(t). One can continue to integrate by parts and convert the semi-infinite sum over n to a finite sum over n to obtain the expression

$$G ( ω ) = {\sum }_{k = c + 1}^{∞} \frac{1}{{( jω )}^{k + 1}} [ {\sum }_{n = 0}^{L} {δ}_{n}^{( k )} {ⅇ}^{- jω n {t}_{0}} + \frac{{\sum }_{j = 0}^{J - 1} {δ}_{L + j + 1}^{( k )} {ⅇ}^{- jω ( L + j + 1 ) {t}_{0}}}{1 - a {ⅇ}^{- jω {Jt}_{0}}} ]$$

where

δₙ^{(k)}=gₙ^{(k)}(0)−gₙ₋₁^{(k)}(t₀)

g₋₁^{(k)}(t₀)=0

That is, δₙ^{(k)} represents the magnitude of the discontinuity at the lower boundary of the n^{th} symbol period of the k^{th} derivative of g(t). This expression for G(ω) shows that the PSD can be computed if one knows the values of these discontinuities.

Assuming that it is possible to form the semi-infinite sum indicated by

$${Δ}_{n} = {\sum }_{k = c + 1}^{∞} \frac{1}{{( jω )}^{k + 1}} {δ}_{n}^{( k )}$$

where Δₙ depends on the indices of summation, then G(ω) can be written as

$$G ( ω ) = {\sum }_{n = 0}^{∞} {Δ}_{n} {ⅇ}^{- jω n {t}_{0}}$$

or in a finite summation form as

$$G ( ω ) = {\sum }_{n = 0}^{L} {Δ}_{n} {ⅇ}^{- jω n {t}_{0}} + \frac{{\sum }_{j = 0}^{J - 1} {Δ}_{L + j + 1} {ⅇ}^{- jω ( L + j + 1 ) {t}_{0}}}{1 - a {ⅇ}^{- jω {Jt}_{0}}}$$

It is readily determined that the magnitude of G(ω) reaches a maximum if all terms in the infinite series expression for G(ω) add in phase. Since the PSD depends directly on G(ω), it also reaches a maximum under the same conditions. Thus, the PSD has an upper bound given by one embodiment as

$$PSD \leq \frac{1}{2 {JM}^{L} {t}_{0}} {\sum }_{t = 0}^{J - 1} {\sum }_{μ} {\vert {\sum }_{n = 0}^{∞} {Δ}_{n} \vert}^{2}$$

This upper bound is equal to the actual answer when ωt₀ is a multiple of 2π. A form of this equation can be easily found wherein the summation over n is finite:

$$PSD \leq \frac{1}{2 {JM}^{L} {t}_{0}} {\sum }_{t = 0}^{J - 1} {\sum }_{μ} {\vert {\sum }_{n = 0}^{L} {Δ}_{n} + \frac{{\sum }_{j = 0}^{J - 1} {Δ}_{L + j + 1}}{1 - a} \vert}^{2}$$

I claim:

1. A method of predicting a power spectral density (PSD) of a modulated signal, the method comprising:
determining an expression in symmetric form that describes the PSD of the modulated signal;
predicting the PSD of the modulated signal using the expression.

2. The method of claim 1, wherein the modulated signal is a transmitted baseband signal.

3. The method of claim 1, wherein the modulated signal is a transmitted signal.

4. The method of claim 1, wherein the modulated signal resides in a channel.

5. The method of claim 1, wherein the modulated signal is a received signal.

6. The method of claim 1, wherein the modulated signal is a received baseband signal.

7. The method of claim 1, wherein the expression is in a Hermitian form.

8. The method of claim 1, wherein the expression is determined by means of a Fourier transform method.

9. The method of claim 1, wherein predicting the PSD of the modulated signal using the expression comprises:
determining an upper bound on the expression.

10. The method of claim 1, wherein predicting the PSD of the modulated signal using the expression comprises:
determining a Bode plot of the expression.

11. A computer-readable medium containing instructions that, when performed by a computer, implements the method of claim 1.

12. A method of predicting a power spectral density (PSD) of a multi-h continuous phase modulated signal, the method comprising:
determining an expression using a Fourier transform method that describes the PSD of the multi-h continuous phase modulated signal;
predicting the PSD of the multi-h continuous phase modulated signal using the expression.

13. The method of claim 12, wherein the multi-h continuous phase modulation is derived from a single-h continuous phase full-response binary modulation.

14. The method of claim 12, wherein the modulated signal has a phase that varies in a piece-wise linear fashion.

15. The method of claim 12, wherein the modulated signal has a phase that varies in a piece-wise raised-cosine fashion.

16. The method of claim 12, wherein the expression has a cosine and sine form.

17. The method of claim 12, wherein the expression has an exponential form.

18. The method of claim 12, wherein the expression has an exponential form with a finite number of summations.

19. The method of claim 12, wherein predicting the PSD of the modulated signal using the expression comprises:
determining an upper bound on the expression.

20. The method of claim 12, wherein predicting the PSD of the modulated signal using the expression comprises:
determining a Bode plot of the expression.

21. An apparatus for predicting a power spectral density (PSD) of a modulated signal, the apparatus comprising:
means for determining an expression in symmetric form that describes the prediction of the PSD of the modulated signal;
means for predicting the PSD of the modulated signal using the expression.

22. The apparatus of claim 21, wherein the modulated signal is derived from a multi-h continuous phase modulation.
